(19) United States
(12) Patent Application Publication
(10) Pub. No.: US 2026/0214937 A1
(43) Pub. Date: Jul. 23, 2026

(54) INSULATED GATE SEMICONDUCTOR DEVICE

(71) Applicant: FUJI ELECTRIC CO., LTD., Kawasaki-shi (JP)

(72) Inventor: Yasuyuki HOSHI, Matsumoto-city (JP)

(73) Assignee: FUJI ELECTRIC CO., LTD., Kawasaki-shi (JP)

(21) Appl. No.: 19/402,565

(22) Filed: Nov. 26, 2025

(30) Foreign Application Priority Data
Jan. 17, 2025 (JP) 2025-006540

(51) Int. Cl. H10D 30/66; H10D 62/10; H10D 62/832; H10D 64/23

(52) U.S. Cl. CPC H10D 30/668; H10D 62/126; H10D 62/8325; H10D 64/252; H10D 62/102

(57) ABSTRACT

The insulated gate semiconductor device includes: a base region; a main electrode region provided on a top surface side of the base region; a plurality of trenches extending through the main electrode region and the base region and arranged at a first interval; a gate electrode buried in each of the trenches via a gate insulating film and configured to form an inversion layer in a region of the base region which region is separated from an interface between the base region and the each of the trenches in response to voltage application; an interlayer insulating film covering the gate electrode and having an opening exposing the main electrode region; and a contact electrode buried in the opening and having a bottom surface in contact with the main electrode region and a top surface wider in width than the main electrode region in an arrangement direction of the trenches.

### CROSS-REFERENCE TO RELATED APPLICATION

This application claims benefit of priority under 35 USC 119 based on Japanese Patent Application No. 2025-006540 filed on January 17, 2025, the entire contents of which are incorporated by reference herein.

### BACKGROUND OF THE INVENTION

### 1 Field of the Invention

This disclosure relates to an insulated gate semiconductor device.

### 2 Description of the Related Art

JP 6631632 B2 (Patent Literature 1) and F.Udrea et al., "Experimental demonstration, challenges, and prospects of the vertical SiC FinFET", 2022 IEEE34th ISPSD, May 2022 (Non-Patent Literature 1), describe a vertical SiC-MOSFET having a trench gate structure incorporating unit cells (functional units of a device) configured with a FinFET structure (Metal Oxide Semiconductor Field Effect Transistor: a MOS field effect transistor including an insulated gate and having a three layer structure of Metal-Oxide Film-Semiconductor).

However, in Patent Literature 1 and Non-Patent Literature 1, the Fin width (the width between gate trenches adjacent to each other) is narrow. As a result, destruction tolerance under large current conditions may decrease in comparison with a normal FET with a large width between gate trenches.

### SUMMARY OF INVENTION

This disclosure is accomplished in view of the above problems, and an object of this disclosure is to provide an insulated gate semiconductor device that can suppress a decrease in destruction tolerance.

In order to achieve the above object, an insulated gate semiconductor device according to one aspect of this disclosure includes: a drift layer of a first conductivity type; a base region of a second conductivity type provided on a top surface side of the drift layer; a main electrode region of the first conductivity type provided on a top surface side of the base region; a plurality of trenches extending through the main electrode region and the base region and arranged at a first interval in a plan view; a gate electrode buried in each of the plurality of trenches via a gate insulating film and configured to form an inversion layer in a region of the base region which region is separated from an interface between the base region and the each of the plurality of trenches in response to voltage application; an interlayer insulating film covering the gate electrode and having an opening exposing the main electrode region; and a contact electrode buried in the opening and having a bottom surface in contact with the main electrode region and a top surface wider in width than the main electrode region in an arrangement direction where the plurality of trenches is arranged.

The top surface of the contact electrode may be wider in width than the bottom surface of the contact electrode.

The contact electrode may have a lateral surface linearly connecting the top surface to the bottom surface in a sectional view.

The contact electrode may have a lateral surface having a curved shape expanding outward to connect the top surface to the bottom surface in a sectional view.

The first interval may be 0.3 μm or less.

The drift layer, the base region, and the main electrode region may be made of silicon carbide or silicon.

Note that the summary of the disclosure does not describe all necessary features of this disclosure. Subcombinations of these features can also be included in the disclosure.

### BRIEF DESCRIPTION OF DRAWINGS

FIG. 1 is a view to describe the positional relationship in a plan view between a gate electrode, a source region, and a base contact region included in an insulated gate semiconductor device according to a first embodiment;

FIG. 2 is a longitudinal sectional view illustrating a sectional configuration taken along a line A-A in FIG. 1;

FIG. 3 is a longitudinal sectional view illustrating part of one unit cell in FIG. 2 in an enlarged manner;

FIG. 4 is a view to describe the positional relationship in a plan view between a contact electrode and an interlayer insulating film included in the insulated gate semiconductor device according to the first embodiment; and

FIG. 5 is a longitudinal sectional view illustrating a sectional configuration of a contact electrode 12 according to Modification 1 of the first embodiment.

### DETAILED DESCRIPTION

With reference to the drawings, the following describes a first embodiment of this disclosure. In the description for the drawings, identical or similar constituents have identical or similar reference signs, and redundant descriptions are omitted. Note that, the drawings are schematic, and the relationship between thickness and flat dimension, the ratio between layer thicknesses, and the like are different from actual ones. In addition, the drawings may include portions having different dimensional relationships or ratios. Further, the first embodiment described below exemplify devices or methods to embody the technical idea of this disclosure, and the technical idea of this disclosure does not limit the material, shape, structure, and the like of a constituent component to those described below.

In the present specification, the source region of a field effect transistor (FET) is "one main electrode region (a first main electrode region)" selectable as the emitter region of an insulated gate bipolar transistor (IGBT). In a thyristor such as an MOS controlled static induction thyristor (SI thyristor), the "one main electrode region" is selectable as the cathode region. The drain region of the FET is "the other main electrode region (a second main electrode region)" of a semiconductor device that is selectable as the collector region in the IGBT or the anode region in the thyristor. When the "main electrode region" is just referred to in the present specification, the "main electrode region" indicates the appropriate one of the first main electrode region and the second main electrode region based on a common general technical knowledge of those skilled in the art.

Further, the definitions of directions such as "up" and "down" in the following description are merely definitions for convenience of the description and do not restrict the technical idea of this disclosure. For example, when a target is rotated by 90° and observed, the "up-down direction" is replaced with the "right-left direction," and when the target is rotated by 180° and observed, the top and bottom are upside down. Also, "top surface" may be read as "front surface," and "bottom surface" may be read as "back surface."

The following description illustratively describes a case where a first conductivity type is n-type, and a second conductivity type is p-type. However, the conductivity types may be reversed such that the first conductivity type is p-type, and the second conductivity type is n-type. Sign "+" to be added to "n" or "p" indicates a semiconductor region having a relatively high impurity concentration in comparison with a semiconductor region without "+," and sign "-" to be added to "n" or "p" indicates a semiconductor region having a relatively low impurity concentration in comparison with a semiconductor region without "-." Note that separate semiconductor regions assigned with "n" may have different impurity concentrations.

### First Embodiment

### Structure of Insulated Gate Semiconductor Device

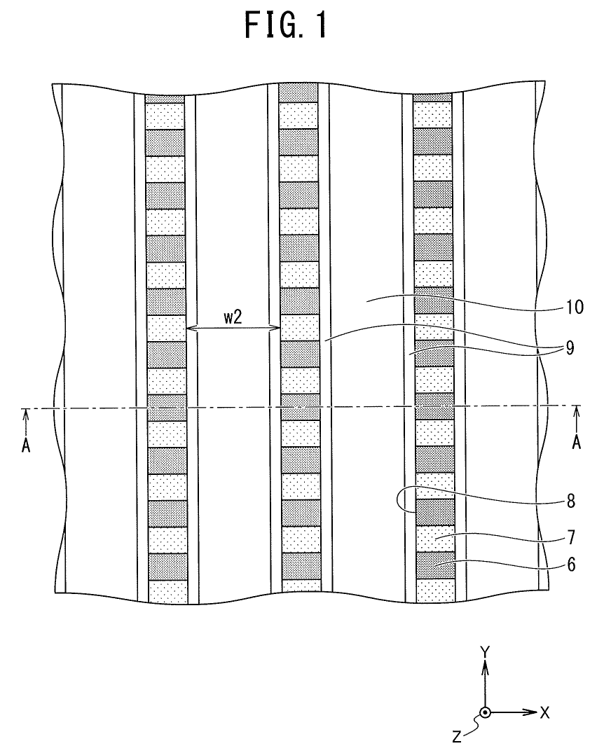

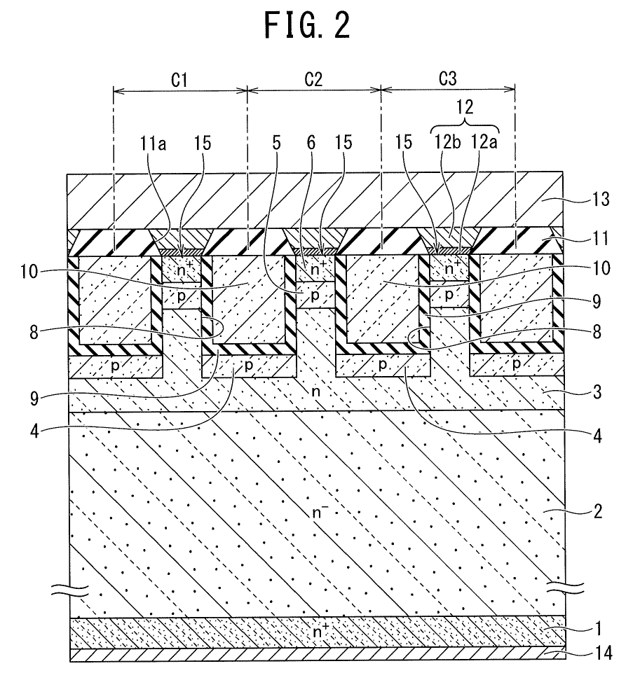

FIGS. 1 to 4 are views illustrating exemplary configurations of an insulated gate semiconductor device (MISFET) according to a first embodiment of this disclosure. The insulated gate semiconductor device according to the first embodiment is a power device and includes a trench gate FET as an active element. The insulated gate semiconductor device according to the first embodiment includes a semiconductor layer, which may be made of silicon carbide (SiC), for example, or may be made of silicon (Si), for example. That the semiconductor layer of the insulated gate semiconductor device is made of SiC or Si may include a case where the semiconductor layer mainly contains SiC or Si. The present embodiment deals with a case where the semiconductor layer of the insulated gate semiconductor device is made of SiC. The present embodiment also deals with a case where the technology of this disclosure is applied to a unit cell configured with a FinFET structure. FIG. 2 illustrates unit cells (functional units of the device) C1, C2, C3 with the FinFET structure. The unit cells C1, C2, C3 with the FinFET structure each includes a Fin section 15. The number of unit cells is not limited to FIG. 2, and a plurality of unit cells is arranged periodically.

The insulated gate semiconductor device according to the first embodiment includes a drift layer 2 of the first conductivity type (n⁻-type). The drift layer 2 is constituted by an epitaxially-grown layer made of SiC, for example. The drift layer 2 has an impurity concentration of approximately about 1 × 10¹⁵ cm⁻³ or more and 5 × 10¹⁶ cm⁻³ or less, for example. The impurity concentration and thickness of the drift layer 2 can be adjusted appropriately according to the voltage rating and other design specifications.

A current spreading layer (CSL) 3 of the first conductivity type (n-type) with a higher impurity concentration than that of the drift layer 2 is selectively provided on the top surface side of the drift layer 2. The bottom surface of the current spreading layer 3 is in contact with the top surface of the drift layer 2. The current spreading layer 3 is constituted by an epitaxially-grown layer made of SiC, for example. The current spreading layer 3 has an impurity concentration of approximately 5 × 10¹⁶ cm⁻³ or more and 5 × 10¹⁷ cm⁻³ or less, for example. Note that the current spreading layer 3 may not necessarily be provided, and in a case where the current spreading layer 3 is not provided, the drift layer 2 may be provided to extend to the region of the current spreading layer 3.

A base region 5 of the second conductivity type (p-type) is provided on the top surface side of the current spreading layer 3. The bottom surface of the base region 5 is in contact with the top surface of the current spreading layer 3. Note that, in a case where the current spreading layer 3 is not provided, the bottom surface of the base region 5 is in contact with the top surface of the drift layer 2. The base region 5 is constituted by an epitaxially-grown layer made of SiC, for example. The base region 5 may be a region where p-type impurities are ion implanted into the current spreading layer 3. The base region 5 has an impurity concentration of approximately 1 × 10¹⁷ cm⁻³ or more and 1 × 10¹⁸ cm⁻³ or less, for example.

First main electrode regions (source regions) 6 of the first conductivity type (n⁺-type) with a higher impurity concentration than that of the drift layer 2 are selectively provided on the top surface side of the base region 5. The source region 6 is a region made of SiC formed by performing ion implantation of n-type impurities on the base region 5, for example. The bottom surface of the source region 6 is in contact with the top surface of the base region 5. The source region 6 has an impurity concentration of approximately 1 × 10¹⁷ cm⁻³ or more and 5 × 10¹⁸ cm⁻³ or less, for example.

Although not illustrated in FIG. 2, base contact regions 7 of the second conductivity type (p⁺-type) with a higher impurity concentration than that of the base region 5 are selectively provided on the top surface side of the base region 5. The base contact region 7 is a region made of SiC formed by performing ion implantation of p-type impurities on the base region 5, for example. The bottom surface of the base contact region 7 is in contact with the top surface of the base region 5. The base contact region 7 has an impurity concentration of approximately 5 × 10¹⁹ cm⁻³ or more and 5 × 10²⁰ cm⁻³ or less, for example.

As illustrated in FIG. 1, the base contact region 7 is provided adjacent to the source region 6 along the Y direction. More specifically, the base contact regions 7 and the source regions 6 are provided alternately along the Y direction. The source region 6 and the base contact region 7 may not be in contact with each other.

A plurality of trenches 8 extending through the base contact regions 7, the source regions 6, and the base regions 5 is provided from the top surfaces of the base contact region 7 and the source region 6 toward the normal direction (the depth direction, the Z direction) of the top surfaces of the base contact region 7 and the source region 6. The trenches 8 form a stripe plane pattern. For example, the trenches 8 are elongated along the Y direction in a plan view and are arranged at an interval (a first interval) along the X direction. The trenches 8 each have a width w2 in their arrangement direction (their short direction), and the width w2 is approximately 0.3 μm or more and 1.0 μm or less, for example. As illustrated in FIG. 2, the right and left lateral surfaces of the trench 8 are in contact with the source region 6, the base region 5, and the current spreading layer 3, and the bottom surface of the trench 8 reaches the current spreading layer 3. Note that, in the case where the current spreading layer 3 is not provided, the right and left lateral surfaces of the trench 8 are in contact with the drift layer 2 instead of the current spreading layer 3, and the bottom surface of the trench 8 reaches the drift layer 2. The trench 8 has a depth of approximately 1 μm, for example. The semiconductor region located between the trenches 8 adjacent to each other serves as the Fin section 15. Each of the Fin sections 15 may have a stripe shape elongated in the rearward direction and the forward direction relative to the surface of paper of FIG. 2, for example. The base contact region 7, the source region 6, the base region 5, and the current spreading layer 3 are provided between the trenches 8 adjacent to each other. Note that, in the case where the current spreading layer 3 is not provided, the drift layer 2 is located between the trenches 8 adjacent to each other. Note that the trenches 8 may form a dotted plane pattern, instead of the stripe plane pattern.

A gate insulating film 9 is provided on the inner surface of the trench 8, more specifically, along the bottom surface and the opposite lateral surfaces of the trench 8. A gate electrode 10 is buried in the trench 8 via the gate insulating film 9. A trench gate insulated gate electrode structure (9, 10) is constituted by the gate insulating film 9 and the gate electrode 10. Note that, in the drawing, the top surface of the gate electrode 10 is located at the same depth position as the top surface of the source region 6, but the top surface of the gate electrode 10 may be slightly recessed to be located at a position deeper than the top surface of the source region 6.

The gate insulating film 9 may be a single layer film composed of any one of a silicon oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, or a composite film formed by stacking some of these films.

The material usable for the gate electrode 10 may be, for example, a polysilicon layer (a doped polysilicon layer) doped with p-type impurities or n-type impurities at a high impurity concentration, or high melting point metals such as titanium (Ti), tungsten (W), or nickel (Ni). The gate insulating film 9 has a thickness of approximately 30 nm or more and 100 nm or less, for example.

A gate bottom protection region 4 of the second conductivity type (p⁺-type) is provided within the current spreading layer 3 and at the bottom of the trench 8. The top surface of the gate bottom protection region 4 is in contact with the bottom surface of the trench 8. The gate bottom protection region 4 has an impurity concentration of approximately 1 × 10¹⁷ cm⁻³ or more and 1 × 10¹⁹ cm⁻³ or less.

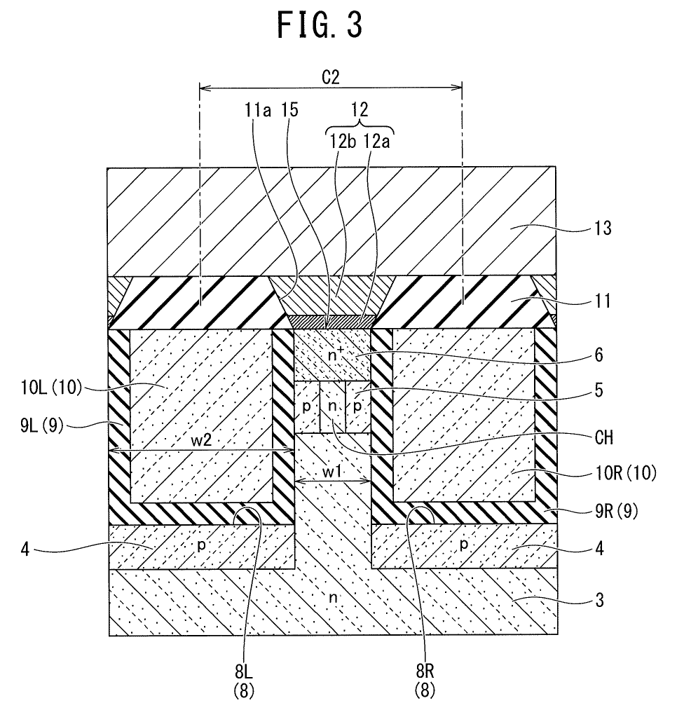

The unit cells C1, C2, C3 illustrated in FIG. 2 have similar configurations. Accordingly, the configuration of the unit cell with the FinFET structure will be further described with reference to FIG. 3 by taking the unit cell C2 as an example. The trench 8, the gate insulating film 9, and the gate electrode 10 located on the left side of the Fin section 15 of the unit cell C2 on the surface of paper may be referred to as a trench 8L, a gate insulating film 9L, and a gate electrode 10L.

The trench 8, the gate insulating film 9, and the gate electrode 10 located on the right side of the Fin section 15 of the unit cell C2 on the surface of paper may be referred to as a trench 8R, a gate insulating film 9R, and a gate electrode 10R.

The Fin section 15 has a width w1, which is a distance between the trench 8L and the trench 8R, namely, the first interval. In addition, the width w1 of the Fin section 15 corresponds to the widths of the base region 5, the source region 6, and the current spreading layer 3 located between the trench 8L and the trench 8R. The width w1 of the Fin section 15 is approximately 0.3 μm or less, for example. More preferably, the width w1 of the Fin section 15 is approximately 0.2 μm or less, for example. The width w1 of the Fin section 15 may be approximately 0.05 μm or more, or approximately 0.1 μm or more, for example. One feature of the FinFET is that the width w1 is small as described above.

The following describes the operation of a normal FET with a sufficiently large width w1 and the operation of the FinFET illustrated in FIG. 3. First, a gate voltage equal to or more than a threshold is applied to the gate electrodes 10L, 10R. In the case of the normal FET, when the gate voltage equal to or more than the threshold is applied to the gate electrode 10, an inversion layer CH is formed along the interface between the base region 5 and the gate insulating film 9. In contrast, in the case of the FinFET illustrated in FIG. 3, the width w1 of the Fin section 15 is sufficiently small, so that voltages from the gate electrodes 10L, 10R are applied to the whole base region 5. As a result, in the base region 5, the inversion layer CH is formed in a region (a bulk region) separated from the interfaces between the base region 5 and the gate insulating films 9L, 9R. For example, the inversion layer CH is formed at a position separated from the interface by approximately 0.05 μm or more and 0.1 μm or less. Also, the inversion layer CH is formed in a central portion of the base region 5 in the right-left direction on the surface of paper, for example. Accordingly, in comparison with the normal FET, in the case of the FinFET, electrons moving in the inversion layer CH are less susceptible to the interface state densities of the interfaces between the base region 5 and the gate insulating films 9L, 9R. As a result, electronic mobility can be raised, and conduction resistance (ON resistance) can be suppressed. Here, SiC is a compound, and the interface state density of SiC in the oxide film is approximately one order of magnitude higher than that of Si. Accordingly, the electron mobility of a gate type semiconductor device formed with SiC is more susceptible to interface state density than a gate type semiconductor device formed with Si. In view of this, the application of the FinFET structure to the gate type semiconductor device formed with SiC provides a solution to the issue of interface state density.

An interlayer insulating film 11 is provided on the top surface side of the gate electrode 10. The interlayer insulating film 11 covers the gate electrode 10. The interlayer insulating film 11 may be, for example, a single layer film such as a silicon oxide film (BPSG film) to which boron (B) and phosphor (P) are added, a silicon oxide film (PSG film) to which phosphor (P) is added, an undoped silicon oxide film called "NSG," which does not contain phosphor (P) and boron (B), a silicon oxide film (BSG film) to which boron (B) is added, and a silicon nitride film (Si₃N₄ film), or a stacked-layer film obtained by stacking some of them. The interlayer insulating film 11 has a thickness of approximately 1 μm or more and 1.5 μm or less, for example. The interlayer insulating film 11 has an opening 11a that exposes the top surfaces of the source region 6 and the base contact region 7. The opening 11a has a tapered sectional shape (a generally trapezoidal shape) that increases in width from bottom (the SiC side) to top. The opening 11a forms a plane pattern extending in a stripe shape in the rearward direction and the forward direction relative to the surface of paper FIG. 2. Although not illustrated herein, the surface of the interlayer insulating film may be covered with a barrier metal film made of titanium, titanium nitride, or the like.

A contact electrode 12 is buried in the opening 11a. The contact electrode 12 has a thickness of approximately 1 μm or more and 1.5 μm or less, for example. The thickness of the contact electrode 12 is approximately the same as that of the interlayer insulating film 11, for example. The bottom surface of the contact electrode 12 is in contact with the top surfaces of the source region 6 and the base contact region 7. The contact electrode 12 includes a lower layer 12a directly in contact with the top surfaces of the source region 6 and the base contact region 7, and an upper layer 12b contact with the top surface of the lower layer 12a. The lower layer 12a is a known ohmic metal layer and is made of nickel (Ni) or a material containing nickel and silicide, for example. The lower layer 12a may be a single layer film or may be a stacked-layer film stacked of multiple types of metals. The lower layer 12a is in low resistance ohmic contact with the source region 6 and the base contact region 7. The upper layer 12b is made of a conductive material such as metal, for example, tungsten (W).

As illustrated in FIG. 3, the width of the contact electrode 12 is wider than the width of the Fin section 15 in a cross sectional view. More specifically, the width of the top surface of the contact electrode 12 is wider than the width of the Fin section 15. The contact electrode 12 has a tapered sectional shape (a generally trapezoidal shape) that increases in width from bottom (the SiC side) to top. The lateral surface of the contact electrode 12 linearly connects the top surface of the contact electrode 12 to the bottom surface thereof.

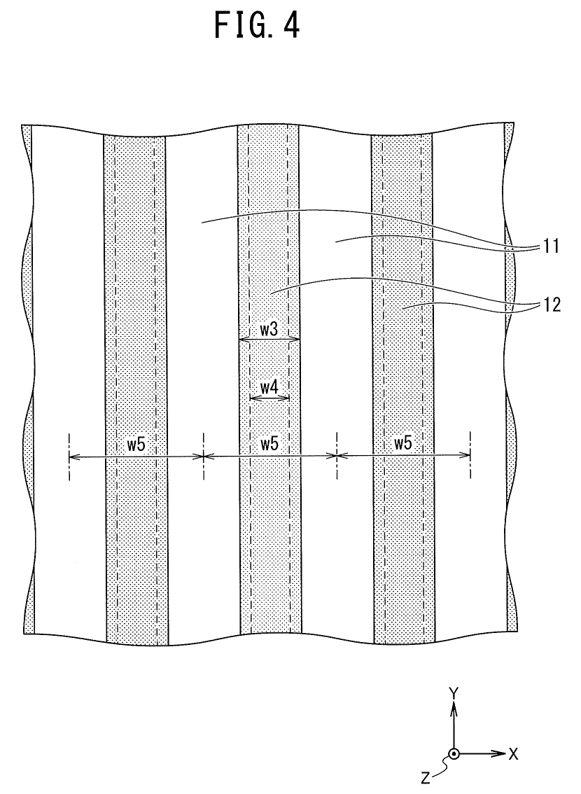

As illustrated in FIG. 4, the contact electrodes 12 form a stripe plane pattern. More specifically, the contact electrodes 12 are elongated along the Y direction in a plan view and are arranged at an interval along the X direction. As illustrated in FIG. 4, a width w3 represents the width of the top surface of the contact electrode 12, and a width w4 represents the width of the bottom surface thereof. The width w3 of the top surface is larger than the width w4 of the bottom surface (w3 > w4). The width w4 of the bottom surface is generally the same as the width w1 of the Fin section 15 so that the bottom surface of the contact electrode 12 is connected to the Fin section 15. The width w3 of the top surface is approximately 1.1 times or more of the width w4 of the bottom surface, for example (w3 ≥ 1.1 × w4). In the meantime, for example, the width w3 of the top surface may be approximately 1.5 times or more of the width w4 of the bottom surface (w3 ≥ 1.5 × w4) or may be approximately twice the width w4 of the bottom surface (w3 ≥ 2 × w4). By setting the widths w3, w4 to such dimensions, the bottom surface of the contact electrode 12 can be connected to the source region 6, and the thickness of the contact electrode 12 as a wiring line can be increased.

The width w3 of the top surface of the contact electrode 12 is less than half of a pitch w5 of the unit cell C2 (w3 < 0.5 × w5). By providing the width w3 with such a dimension, the interlayer insulating film 11 is exposed between the contact electrodes 12. Note that the pitch w5 of the unit cell C2 has a dimension corresponding to the sum of the width w1 of the Fin section 15 and the width w2 of the trench 8 (w5 = w1 + w2).

A first main electrode (source electrode) 13 is provided to cover the top surfaces of the interlayer insulating film 11 and the contact electrode 12. The source electrode 13 is in contact with the contact electrode 12 such that they are electrically connected to each other. The source electrode 13 is made of a metal such as aluminum (Al), aluminum-silicon (Al-Si), aluminum-silicon-copper (Al-Si-Cu), or aluminum-copper (Al-Cu), for example. Since the interlayer insulating film 11 is exposed between the contact electrodes 12, the adhesion between the source electrode 13 and the underlying layer can be enhanced.

A second main electrode region (drain region) 1 of the first conductivity type (n⁺ -type) with a higher impurity concentration than that of the drift layer 2 is provided on the bottom surface side of the drift layer 2. The drain region 1 is constituted by a semiconductor substrate (SiC substrate) made of 4H-SiC, for example. The drain region 1 has an impurity concentration of approximately 1 × 10¹⁹ cm⁻³ or more and 3 × 10²⁰ cm⁻³ or less, for example. The drain region 1 has a thickness of approximately 30 μm or more and 500 μm or less, for example. Note that a dislocation conversion layer or a recombination promotion layer, which is an n-type buffer layer with an impurity concentration higher than that of the drift layer 2 and lower than that of the drain region 1, may be provided between the drift layer 2 and the drain region 1.

A second main electrode (drain electrode) 14 is provided on the bottom surface side of the drain region 1. The drain electrode 14 may be a single layer film made of gold (Au), for example, or a metal film formed by stacking titanium (Ti), nickel (Ni), and Au in this order from the drain region 1 side, and a metal film made of molybdenum (Mo), tungsten (W), or the like may be further stacked as the lowest layer under the drain electrode 14. A drain contact layer such as a nickel silicide (NiSiₓ) film for an ohmic contact may be provided between the drain region 1 and the drain electrode 14. Note that, in the present specification, the expression "main electrode" alone shall be understood to denote the appropriate one of the first main electrode and the second main electrode based on a common general technical knowledge of those skilled in the art.

At the time of operating the insulated gate semiconductor device according to the first embodiment, a positive voltage is applied to the drain electrode 14 with the source electrode 13 at ground potential. When a positive voltage equal to or more than a threshold is applied to the gate electrodes 10 in that state, an inversion layer (channel) CH is formed in a region of the base region 5 which region is separated from the interface between the base region 5 and the trench 8 to establish an ON state, as illustrated in FIG. 3. In the ON state, current flows from the drain electrode 14 to the source electrode 13 via the drain region 1, the drift layer 2, the current spreading layer 3, the inversion layer CH of the base region 5, the source region 6, and the contact electrode 12. In the meantime, in the case where the voltage applied to the gate electrodes 10 is less than the threshold, no inversion layer CH is formed in the base region 5, so that the insulated gate semiconductor device enters an OFF state, and no current flows from the drain electrode 14 to the source electrode 13.

### Main Effect of First Embodiment

With the insulated gate semiconductor device according to the first embodiment, the width of the contact electrode 12 is larger than the width of the source region 6. Since the thickness of the contact electrode 12, serving as a wiring line, is increased, it is possible to suppress electric resistance caused when current flows through the Fin section 15 and the contact electrode 12. Accordingly, even in a case where heavy current flows through the Fin section 15 and the contact electrode 12, it is possible to suppress electric field concentration because electric resistance is suppressed, thereby making it possible to suppress malfunctions caused by a parasitic transistor. Hereby, it is possible to improve destruction tolerance (SW tolerance, short circuit tolerance) at the time when heavy current flows.

In the insulated gate semiconductor device according to the first embodiment, the width of the top surface of the contact electrode 12 is larger than the width of the source region 6. Hereby, the thickness of the contact electrode 12, serving as a wiring line, can be increased without being constrained by the width of the source region 6.

In the insulated gate semiconductor device according to the first embodiment, the width of the top surface of the contact electrode 12 is larger than the width of the source region 6. Accordingly, the thickness of the contact electrode 12, serving as a wiring line, can be increased by widening the top surface thereof while the contact electrode 12 is connected to the Fin section 15 having a narrow width.

### Modification 1 of First Embodiment

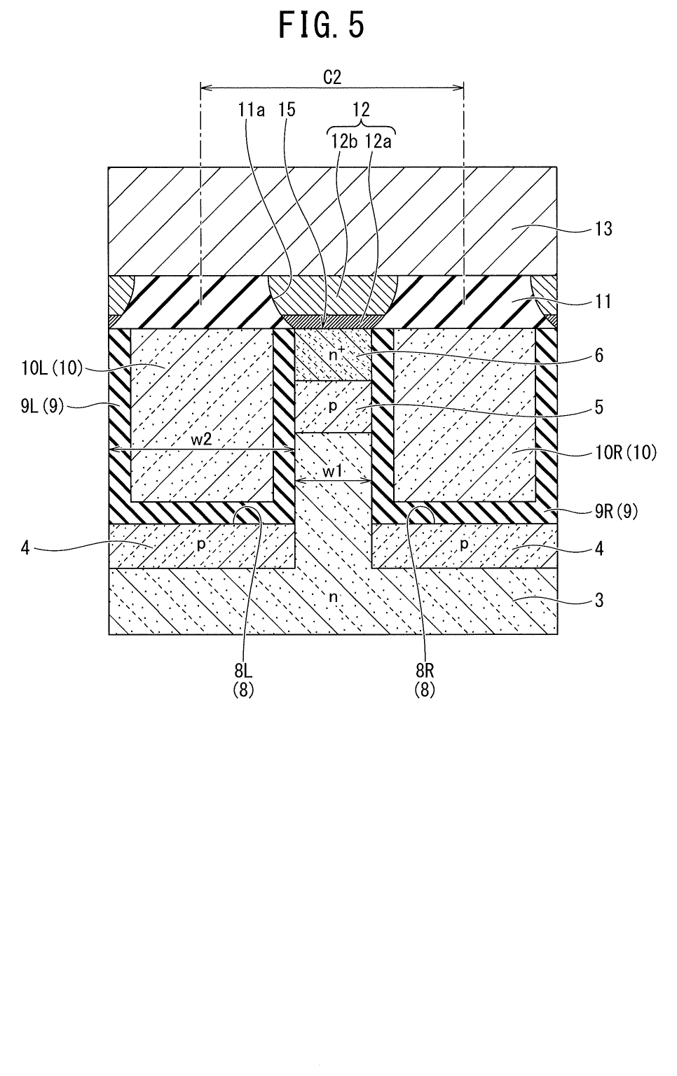

In an insulated gate semiconductor device according to Modification 1 of the first embodiment in this disclosure, the lateral surface of the contact electrode 12 has a curved shape expanding outward to connect the top surface of the contact electrode 12 to the bottom surface thereof, in a cross sectional view as illustrated in FIG. 5. With this modification, the thickness of the contact electrode 12 can be increased more.

### Other Embodiments

The first embodiment of this disclosure has been described above, but it should not be understood that the description and the drawings as part of this disclosure restrict the disclosure. Various alternative embodiments, examples, and operational technologies will become clear to a person skilled in the art from this disclosure.

For example, the FET is described as an example of the semiconductor device according to the first embodiment. However, the present invention is also applicable to an insulated gate bipolar transistor (IGBT) configured such that a p⁺-type collector region is provided instead of the n⁺-type drain region 1. Other than a single IGBT, the present invention is also applicable to a reverse conductive IGBT (RC-IGBT) or a reverse blocking insulated gate bipolar transistor (RB-IGBT).

For example, the trenches 8 according to the first embodiment form a stripe plane pattern but may form a dotted plane pattern.

The configurations disclosed in the first embodiment can be combined appropriately as far as no consistency occurs. It is needless to say that this disclosure includes various embodiments and so on that are not described herein. Accordingly, the technical scope of this disclosure is determined only by the invention specification matter according to appropriate claims from the above description.

1. An insulated gate semiconductor device comprising:
a drift layer of a first conductivity type;
a base region of a second conductivity type provided on a top surface side of the drift layer;
a main electrode region of the first conductivity type provided on a top surface side of the base region;
a plurality of trenches extending through the main electrode region and the base region and arranged at a first interval in a plan view;
a gate electrode buried in each of the plurality of trenches via a gate insulating film and configured to form an inversion layer in a region of the base region which region is separated from an interface between the base region and the each of the plurality of trenches in response to voltage application;
an interlayer insulating film covering the gate electrode and having an opening exposing the main electrode region; and
a contact electrode buried in the opening and having a bottom surface in contact with the main electrode region and a top surface wider in width than the main electrode region in an arrangement direction where the plurality of trenches is arranged.

2. The insulated gate semiconductor device according to claim 1, wherein
the top surface of the contact electrode is wider in width than the bottom surface of the contact electrode.

3. The insulated gate semiconductor device according to claim 2, wherein
the contact electrode has a lateral surface linearly connecting the top surface to the bottom surface in a sectional view.

4. The insulated gate semiconductor device according to claim 2, wherein
the contact electrode has a lateral surface having a curved shape expanding outward to connect the top surface to the bottom surface in a sectional view.

5. The insulated gate semiconductor device according to claim 1, wherein
the first interval is 0.3 μm or less.

6. The insulated gate semiconductor device according to claim 1, wherein
the drift layer, the base region, and the main electrode region are made of silicon carbide or silicon.
